(19) United States
(12) Patent Application Publication
(10) Pub. No.: US 2026/0251686 A1
(43) Pub. Date: Aug. 27, 2026

(54) STRUCTURE FOR CURRENT SENSING AND METHOD OF MANUFACTURING THE SAME

(71) Applicant: CYNTEC CO., LTD., Hsinchu (TW)

(72) Inventors: Kuang-Feng Li, Hsinchu (TW); Ming-Feng Lee, Hsinchu (TW); Pei-Yuan Chen, Hsinchu (TW); Chih-Tai Cheng, Hsinchu (TW)

(73) Assignee: CYNTEC CO., LTD., Hsinchu (TW)

(21) Appl. No.: 19/062,078

(22) Filed: Feb. 25, 2025

(51) Int. Cl. G01R 19/00; G01R 1/20

(52) U.S. Cl. CPC G01R 19/0092; G01R 1/203

(57) ABSTRACT

A structure for current sensing is provided in the present disclosure, including a leadframe composed of a first terminal and a second terminal for measuring a current, a sensing resistor portion positioned between the first terminal and the second terminal and current rectifying portions coupling the first terminal and the second terminal with the sensing resistor portion and leads extending from the sensing resistor portion, and a die mounted on the leadframe and electrically coupled to the leads.

### BACKGROUND OF THE DISCLOSURE

### 1. Field of the Disclosure

The present disclosure relates to a structure, and more specifically, to an IC package structure for current sensing and method of manufacturing the same.

### 2. Description of the Related Art

Current measurements are used in electronic systems to provide feedback verifying operation is within acceptable margins and to detect potential fault conditions. Analyzing the current level within a system helps diagnose unintended or unexpected operating modes, enabling adjustments to enhance reliability or to protect the system components from damage. Current flow is typically measured by the voltage drop across a sensing element, such as a current sensing resistor (CSR), e.g. shunt resistor. The magnitude of the current can vary extensively, from picoamps (pA) to tens of thousands of amperes (A). In this process, the current sensing resistor works in conjunction with other components, such as an operational amplifier (OPA), an analog-to-digital convertor (ADC) and/or microcontroller (MCU), to achieve accurate current sensing.

In conventional skill, the current sensing resistor (CSR) is typically in the form of discrete component mounted on a PCB, with other necessary components, such as the operational amplifier, also implemented as discrete parts on the same PCB board. In these designs, the current sensing resistor is electrically coupled to the operational amplifier via PCB traces, which may introduce noise and degrade the quality of the signal in the measurement. As a result, an RC filter is often required in the circuit for noise filtering, complicating the PCB layout and increasing the design time. Furthermore, since the resistance of the current sensing resistor is very small, usually on the order of milliohms (mΩ), the shape of current path and the position of the current sensing resistor may lead to significant resistance deviations, especially when measuring high current. These deviations can negatively impact the accuracy of current measurements. Accordingly, there is a need for those of skilled in the art to improve the design of existing current sensing component, in order to address the aforementioned challenges.

### SUMMARY OF THE DISCLOSURE

In light of the conventional techniques described above, the present disclosure hereby introduces a novel structure, which is characterized by utilizing parts of the leadframe within the structure as a current sensing resistor (CSR) required for current measurement. Additionally, the operational amplifier (OPA) necessary for the current measurement is designedly integrated into a die, which is mounted on the leadframe, thereby constituting an integrated circuit within the package structure.

One aspect of the present disclosure is to provide a structure for current sensing, including: a leadframe, including: a first terminal for measuring a current; a second terminal positioned different from the first terminal; a sensing resistor portion positioned between the first terminal and the second terminal; a plurality of current rectifying portions respectively positioned between the first terminal and the sensing resistor portion, and between the second terminal and the sensing resistor portion, wherein the current rectifying portions couple the first terminal and the second terminal with the sensing resistor portion; and a plurality of leads extending from the sensing resistor portion; a die mounted on the leadframe, wherein the leads are coupled to the die; and a molding compound encapsulating the leadframe and the die.

Another aspect of the present disclosure is to provide a method of manufacturing a structure for current sensing, including: providing a leadframe, wherein the leadframe includes: a first terminal for measuring a current; a second terminal for measuring the current, wherein the second terminal is different from the first terminal; a sensing resistor portion positioned between the first terminal and the second terminal; a plurality of current rectifying portions respectively between the first terminal and the sensing resistor portion and between the second terminal and the sensing resistor portion, and the current rectifying portions couple to the first terminal and the second terminal with the sensing resistor portion; and a plurality of leads extending from the sensing resistor portion; mounting a die on the leadframe; electrically coupling the leads to the die; and encapsulating the leadframe and the die with a molding compound.

These and other objectives of the present disclosure will no doubt become obvious to those of ordinary skill in the art after reading the following detailed description of the preferred embodiment that is illustrated in the various figures and drawings.

### BRIEF DESCRIPTION OF THE DRAWINGS

FIG. 1 presents a schematic diagram of a current sensing circuit according to one embodiment of the present disclosure;

FIG. 2 presents a schematic top view of a current sensing resistor in the structure according to one embodiment of the present disclosure;

FIG. 3 presents a schematic top view of a current sensing resistor in the structure according to an alternative embodiment of the present disclosure;

FIG. 4 presents a schematic top view of a current sensing resistor in the structure according to another alternative embodiment of the present disclosure;

FIG. 5 presents a perspective view of the sensing resistor portion and the current rectifying portion of the current sensing resistor according to one embodiment of the present disclosure;

FIG. 6A presents a schematic top view of a leadframe and a die in the structure according to one embodiment of the present disclosure;

FIG. 6B presents an isometric view of the leadframe and the die in FIG. 6A;

FIG. 6C presents a schematic top view of a leadframe and a die in the structure according to an alternative embodiment of the present disclosure;

FIG. 6D presents a schematic top view of a leadframe and a die in the structure according to another alternative embodiment of the present disclosure;

FIG. 7A presents a schematic top view of a leadframe and a die in the structure according to another embodiment of the present disclosure;

FIG. 7B presents an isometric view of the leadframe and the die in FIG. 7A;

FIG. 8 presents an isometric view of the structure for current sensing according to one embodiment of the present disclosure; and

FIG. 9 presents a flowchart of manufacturing the structure for current sensing according to one embodiment of the present disclosure.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

Detailed reference will now be made to exemplary embodiments of the disclosure, as illustrated in the accompanying drawings, to better understand and implement the present disclosure and to achieve the intended technical effects. It should be understood that the following description is provided by way of example only and is not intended to limit the scope of the present disclosure. Various embodiments and features of the present disclosure, which do not conflict with each other, may be combined and rearranged in different ways. Modifications, equivalents, or improvements to the present disclosure, without departing from its spirit and scope, are readily understood by those skilled in the art and are intended to be encompassed within the scope of this disclosure.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something). Further, spatially relative terms, such as “beneath,” “below,” “lower,” “above,” “upper,” and the like, may be used herein for ease of description to describe one element or feature relationship to another element(s) or feature(s) as illustrated in the figures.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or through holes are formed) and one or more dielectric layers.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. Additionally, the term “based on” may be understood as not necessarily intended to convey an exclusive set of factors, but may allow for the presence of other factors not necessarily expressly described, again depending at least in part on the context.

It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

The following embodiments and figures will be described with reference to a single IC package structure, representing one unit of an IC chip after package singulation. However, it should be noted that, prior to package singulation, multiple dies may be bonded to a single leadframe, with a single molding compound encapsulating all the dies and vertical connections. For simplicity of illustration, the PCB board to which the leadframe is connected will not be depicted in the drawings.

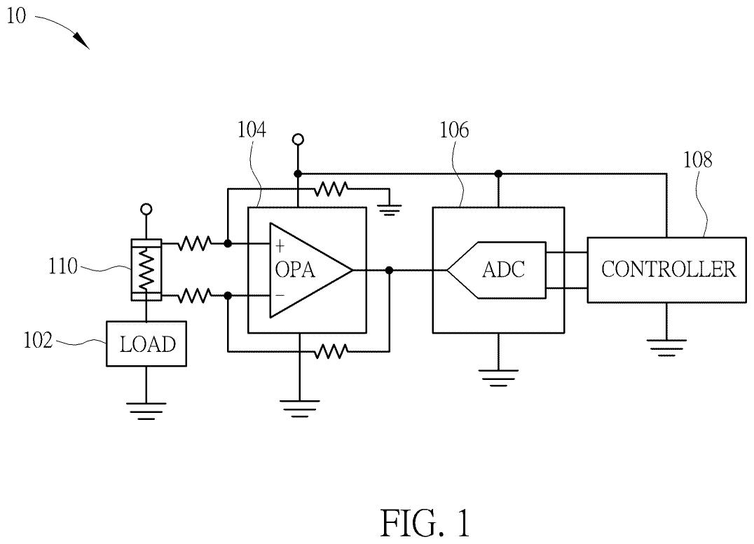

First, referring to FIG. 1, which presents a schematic diagram of the current sensing circuit 10 as embodied in the present disclosure. Generally, a typical current sensing circuit 10 consists of a current sensing resistor (CSR) 110, a load 102, an operational amplifier (OPA) 104, an analog-to-digital convertor (ADC) 106 and a microcontroller (MCU) 108. In this configuration, the current to be measured is input through one terminal of the current sensing resistor 110 and output through the other terminal to the main circuit, with the load 102 disposed in between to adjust and regulate the current flow. Additionally, the load 102 may play a role in protection and control functions within an overcurrent protection circuit. If the current flowing through the load exceeds a preset threshold, the current sensor can trigger a circuit breaker or current-limiting device, thereby preventing potential damage to the load or circuit.

Still referring to FIG. 1, the other two terminals of the current sensing resistor 110 are coupled to the operational amplifier 104. Specifically, one terminal is coupled to the non-inverting input (+) and the other to the inverting input (−) of the operational amplifier 104. The operational amplifier 104 is typically configured as a differential amplifier, which amplifies the voltage difference across the current sensing resistor. The output of the operational amplifier then provides an amplified signal to the analog-to-digital converter (ADC) 106. Since the current sensing resistor is usually a low-value resistor (on the order of milliohms) that generates a small voltage when current flows through it, the operational amplifier 104 is used to amplify the tiny voltage to ensure accurate current measurement.

Still referring to FIG. 1, the analog-to-digital converter 106 is responsible for converting the analog, amplified voltage signal measured by the current sensing resistor 110 into a digital signal for further processing and analysis by the coupled microcontroller 108. Parameters of the ADC, such as resolution, sampling rate, input range and signal-to-noise ratio, directly affect influence the accuracy and response speed of the current measurement. With precise ADC conversion, the current sensing circuit can achieve high-precision and fast-response current monitoring, providing reliable data for various applications. The primary function of the microcontroller 108 is to process signals from the current sensing resistor 110 and the operational amplifier 104, enabling tasks such as current measurement, data calculation, control logic, alarm activation and protection. Additionally, the microcontroller 108 may support multiple communication interfaces for data transmission, offer control output for specific actions, and allow flexible algorithm configuration through embedded software.

It should be noted that, in the embodiment of the present disclosure, the current sensing resistor 110 and operational amplifier 104 within the current sensing circuit 10 are integrated and modularized as a discrete component, such as an IC chip or package structure. This approach significantly differs from conventional practices, where the current sensing resistor and operational amplifier are typically implemented as separate discrete components mounted on a PCB. With this design, the current sensing resistor 110 is not electrically coupled to the operational amplifier 104 via PCB traces, thereby minimizing or even eliminating noise in the current measurement. As a result, an RC filter becomes unnecessary in the current sensing circuit 10.

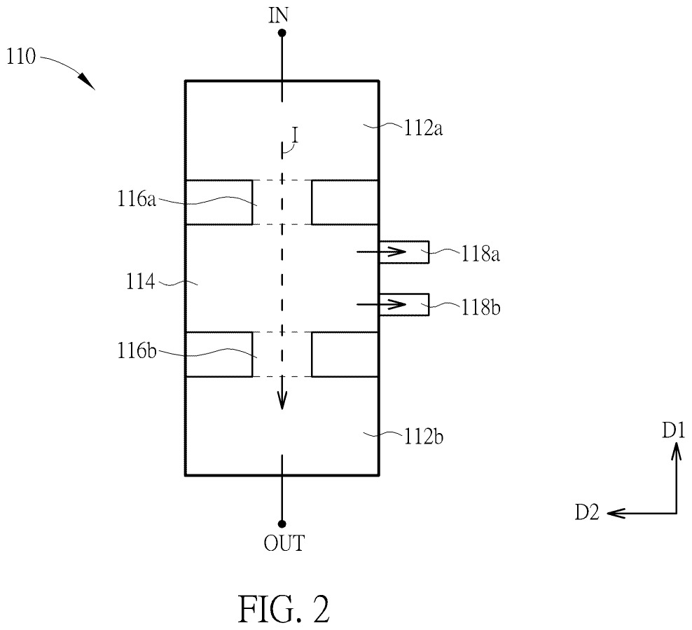

Referring to FIG. 2, which provides a schematic top view of the current sensing resistor 110 within the structure according to one embodiment of the present disclosure. The following description will explain how the present disclosure integrates the current sensing resistor 110 and the operational amplifier 104 into a single discrete component.

The current sensing resistor 110 is part of a leadframe within the structure of the present disclosure, which can be specifically applied in IC packaging as an IC package structure. As illustrated in FIG. 2, the current sensing resistor 110 substantially consists of a first terminal 112a, a second terminal 112b, a sensing resistor portion 114 and a plurality of current rectifying portions, for example, 116a and 116b. From the layout perspective, the first terminal 112a and second terminal 112b are positioned opposite each other along a first direction D1. The sensing resistor portion 114 is placed between the first terminal 112a and second terminal 112b, with the current rectifying portions 116a and 116b arranged therebetween to couple to two opposite sides of the sensing resistor portion 114 to the first terminal 112a and the second terminal 112b, respectively, along the first direction D1. The first terminal 112a and current rectifying portion 116a are preferably symmetrical to the second terminal 112b and current rectifying portion 116b with respect to the sensing resistor portion 114 along the first direction D1. In addition to the first terminal 112a, second terminal 112b, sensing resistor portion 114 and current rectifying portions 116a and 116b, the current sensing resistor 110 also includes a plurality of leads 118a and 118b, which are used to output the sensing signal for amplification. In this embodiment, the leads 118a and 118b extend from the same side of the sensing resistor portion 114, for example, along a second direction D2, which is preferably perpendicular to the first direction D1.

From an operation perspective, the first terminal 112a of the current sensing resistor 110 is coupled to an terminal IN of an external circuit, such as a PCB, which supplies the current I to be measured. The current I flows sequentially through the first terminal 112a, current rectifying portions 116a, sensing resistor portion 114, current rectifying portions 116b, and finally to another terminal OUT of the external circuit along the first direction D1. Optionally, the first terminal 112a and the second terminal 112b may also be used adaptively as an output terminal or an input terminal for detecting a current signal. As the current I passes through the sensing resistor portion 114, a small voltage drop, typically on the order of millivolts (mV), is generated across the resistor. This voltage drop is linearly proportional to the current flowing through the sensing resistor portion 114 and is transmitted to an operational amplifier (e.g., 104 in FIG. 1) as an analog signal for amplification through the leads 118a and 118b.

Still referring to FIG. 2, the current rectifying portions, e.g., 116a and 116b, are positioned between the sensing resistor portion 114, the first terminal 112a, and the second terminal 112b. The current rectifying portions 116a and 116b are located on opposite sides of the sensing resistor portion 114 along the first direction D1. More preferably, these current rectifying portions 116a and 116b are perfectly aligned along the first direction D1. Since different shapes of the current path can lead to varying current densities and effective resistances in the current sensing resistor 110, the current rectifying portions 116a and 116b are designed to guide the current I flowing through the sensing resistor portion 114 along the first direction D1, eliminating the aforementioned effects of the current path.

Additionally, as shown in FIG. 2, the width of the current rectifying portions 116a and 116b along the second direction D2 is intentionally narrower than that of the sensing resistor portion 114. This design further helps to rectify the current I passing through the current rectifying portions 116a and 116b, minimizing resistance deviations during measurement-especially when the current being measured is very large-thus significantly enhancing the accuracy of current measurement. This is an advantage of the present disclosure's circuit design.

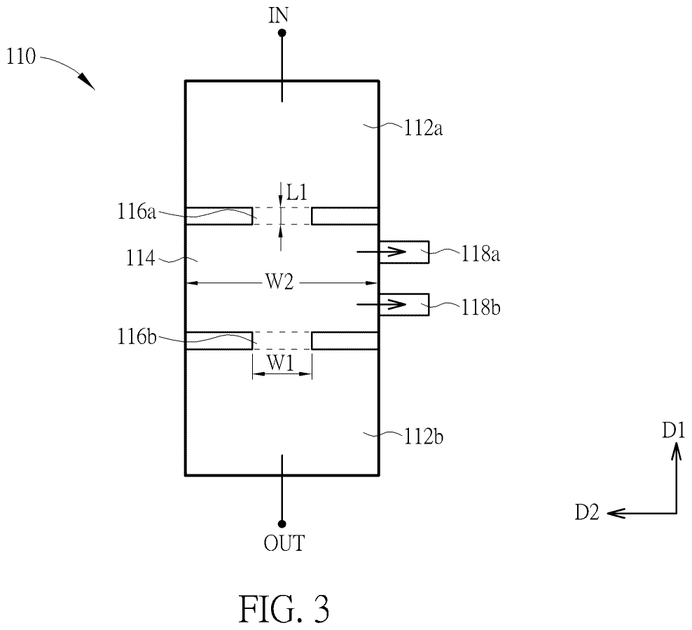

Referring now to FIG. 3, which presents a schematic top view of a current sensing resistor in the structure according to an alternative embodiment of the present disclosure. This embodiment is similar to the previous one, with the difference being that the ratio of the length L1 of the current rectifying portions 116a and 116b along the first direction D1 to a width W1 of the current rectifying portions 116a and 116 along the second direction D2 is greater than that of the previous embodiment. This design further minimizes resistance deviations during measurement. With respect to the dimensions of the components in the current sensing resistor 110, the ratio of the length L1 along the first direction D1 to the width W1 along the second direction D2 of the current rectifying portions 116 a and 116 b is preferably over 0.02, and especially over 0.03. The ratio of the width W1 of the current rectifying portions 116a and 116b to the width W2 along the second direction D2 of the sensing resistor portion 114 is preferably below 0.9, and especially below 0.8.

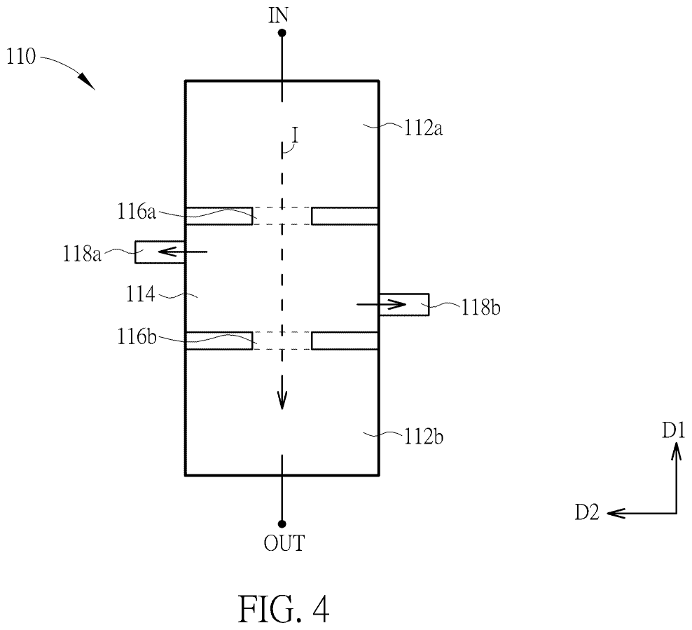

Referring now to FIG. 4, which presents a schematic top view of a current sensing resistor in the structure according to another alternative embodiment of the present disclosure. This embodiment is similar to the previous one, with the difference being that the leads 118a and 118b extend from opposite sides of the sensing resistor portion 114 along the second direction D2, as opposed to originating from the same side. This design further minimizes resistance deviations during measurement, as the sensing signals are output from opposite sides, preventing any interference between them.

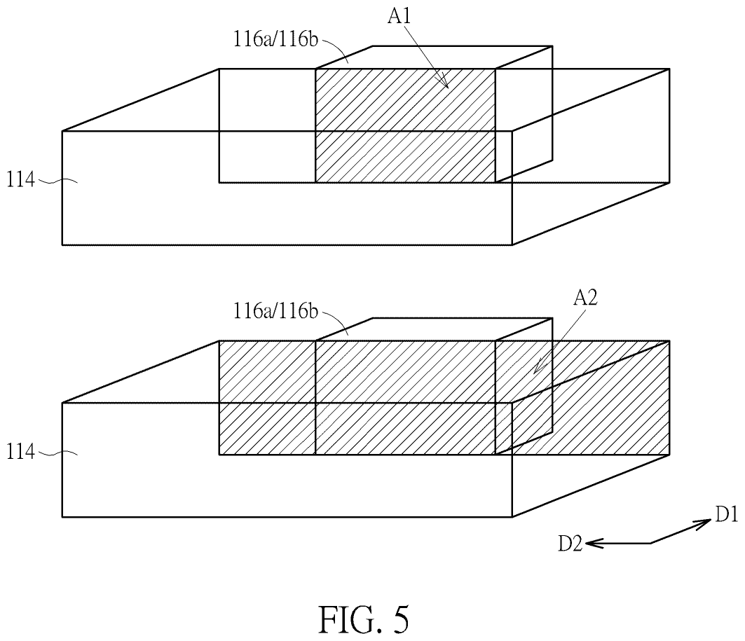

Referring now to FIG. 5, which presents a perspective view of the sensing resistor portion 114 and the current rectifying portion 116a/116b of the current sensing resistor according to an embodiment of the present disclosure. In addition to the ratio of the widths of the current rectifying portions 116a/116b to the sensing resistor portion 114, the cross-sectional areas of these portions along the first direction D1 may rectify the current passing through the sensing resistor and minimize resistance deviations during measurement. As illustrated in FIG. 5, the cross-sectional areas A1 of the current rectifying portion 116a/116b are intentionally designed to be smaller than the cross-sectional areas A2 of the sensing resistor portion 114. This design, similar to the width ratio of the portions, further enhances the rectification of the current through the current rectifying portions 116a and 116b, thereby minimizing resistance deviations and significantly improving the accuracy of current measurements. The thickness of the current rectifying portion 116a/116b in the third direction D3 is preferably, though not necessarily, designed to be equal to that of the sensing resistor portion 114.

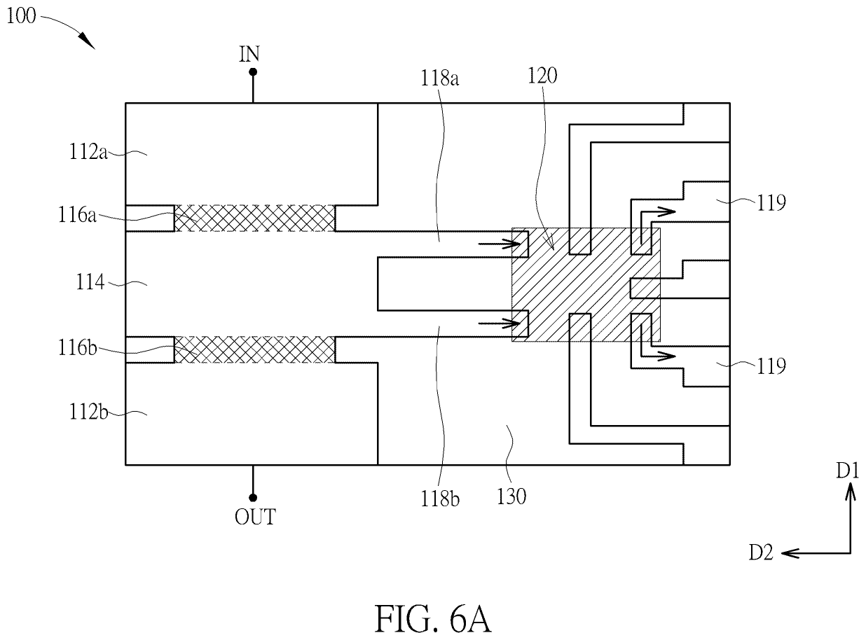

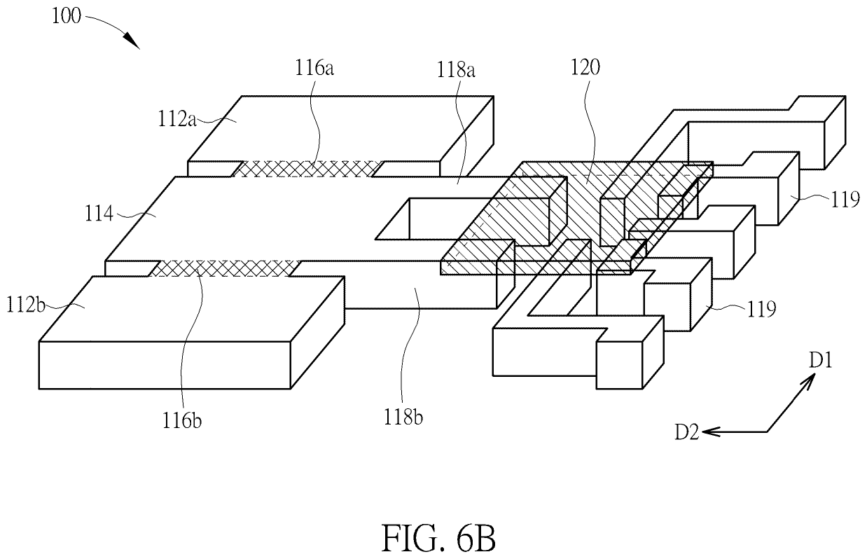

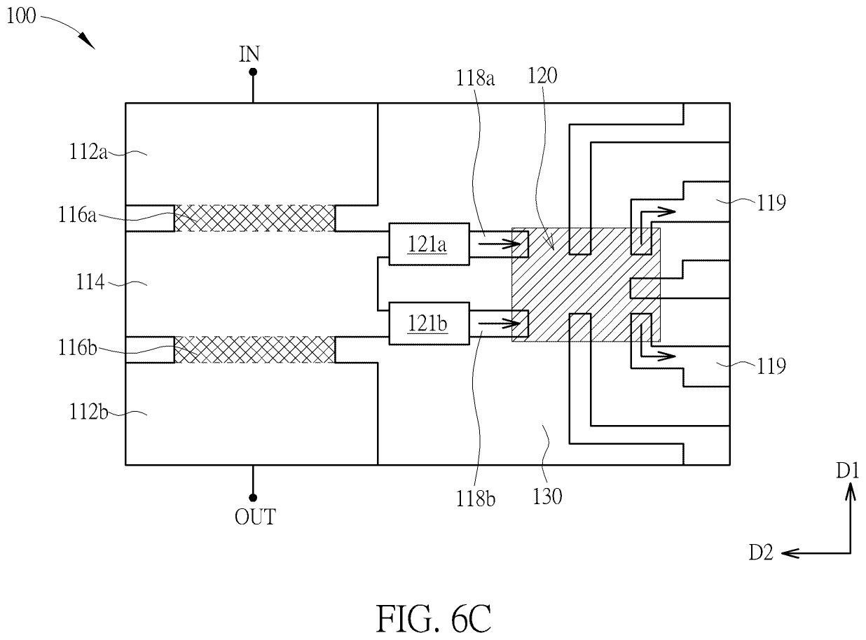

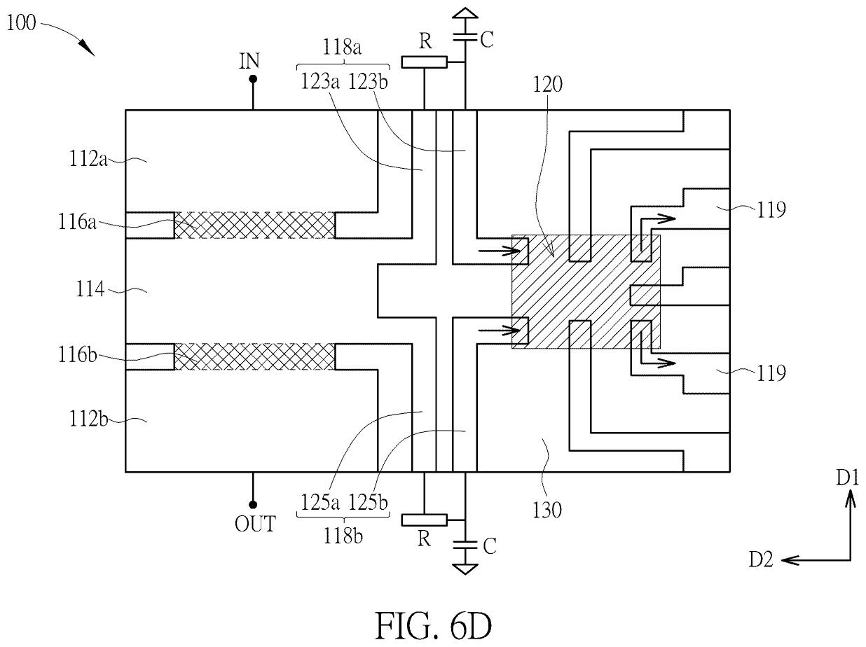

Referring now collectively to FIG. 6A and FIG. 6B, which respectively illustrate a schematic top view and an isometric view of a leadframe 100 and a die 120 within the structure as depicted in one embodiment of the present disclosure. The current sensing resistor 110 is integrated into the leadframe 100 in the structure. As shown in FIG. 6A and FIG. 6B, all of the aforementioned portions of current sensing resistor 110, including the first terminal 112a, second terminal 112b, current rectifying portion 116a/116b, sensing resistor portion 114 and leads 118a/118b are parts of the leadframe 100. The current to be measured is supplied from the terminal IN of an external circuit, such as a PCB, and flows sequentially through the first terminal 112a, current rectifying portions 116a, sensing resistor portion 114, current rectifying portions 116b, and ultimately to another terminal OUT of the external circuit along the first direction D1. As the current passes through the sensing resistor portion 114, a small voltage drop is generated, which is transmitted as a sensing signal to the die 120 mounted on the leadframe 120. This signal is conveyed via the leads 118a and 118b, with each lead coupled to a corresponding terminal (e.g., pads, not shown) on the die 120.

Still referring to FIG. 6A and FIG. 6B, the operational amplifier (such as 104 shown in FIG. 1), used for current measurement, is integrated into the die 120. This die 120 is mounted on the leadframe 100 and forms part of the structure of the present disclosure, enabling the current sensing resistor 110 and the operational amplifier 104 to be combined into a discrete component (e.g., a chip). The sensing signal transmitted through the leads 118a and 118b is then amplified by the operational amplifier 104 in the die 120, producing an amplified signal suitable for subsequent processing and analysis. The amplified signal is then output to an external circuit, such as a PCB, through additional leads 119 of the leadframe 100, which is electrically coupled to the die 120. This amplified signal can subsequently be processed or analyzed by other components mounted on the PCB, such as the analog-to-digital converter 106 and the microcontroller 108, as depicted in FIG. 1. With this design, the current sensing resistor is not electrically coupled to the operational amplifier 104 via PCB traces, as is common in conventional designs, thereby minimizing or even eliminating noise in the current measurement. As a result, an RC filter becomes unnecessary in the current sensing circuit. Additionally, the sensing signal is transmitted through the leads 118a/118b, which extend along the same side of the sensing resistor portion 114 in the second direction D2. As a result, the die 120 is positioned on one side of the sensing resistor portion 114 along the second direction D2, which is perpendicular to the current path in the first direction D1.

Furthermore, in an alternative embodiment of the present disclosure, the leads 118a/118b may be coupled to the die 120 through other components. For instance, as illustrated in FIG. 6C, the leads 118a/118b are initially coupled to resistors 121a/121b, which serve to adjust the sensing voltage, before being routed to the die 120.

Furthermore, in another embodiment of the present disclosure, the leads 118a/118b may be configured in an L-shape to route to an external RC filter circuit, tailored to meet customer requirements, instead of being directly coupled to the die 120. For instance, as shown in FIG. 6D, each lead 118a/118b is formed in an L-shape and split into two segments 123a/123b and 125a/125b, with one segment 123a, 125a coupled to one terminal of a resistor R in the RC filter circuit, and the other segment 123b, 125b coupled to both the second terminal of the resistor R and one terminal of a capacitor C in the RC filter circuit, before being routed back to the die 120.

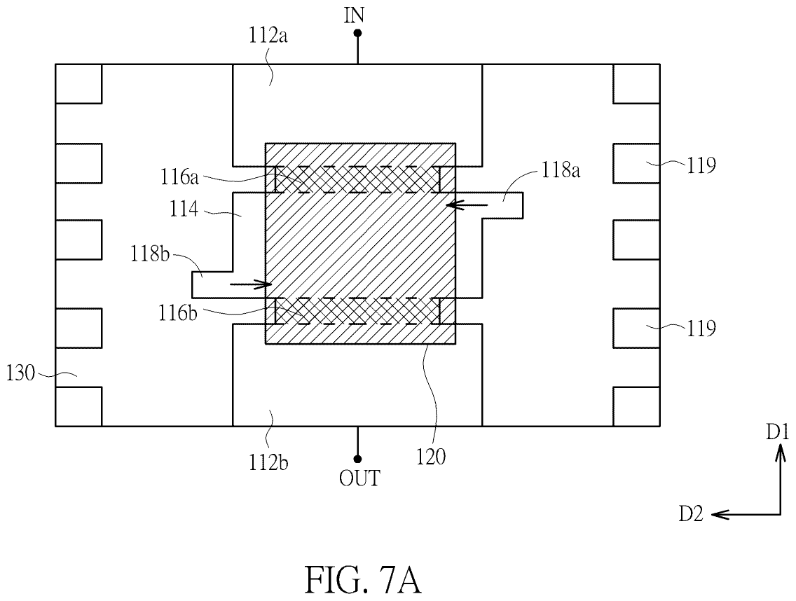

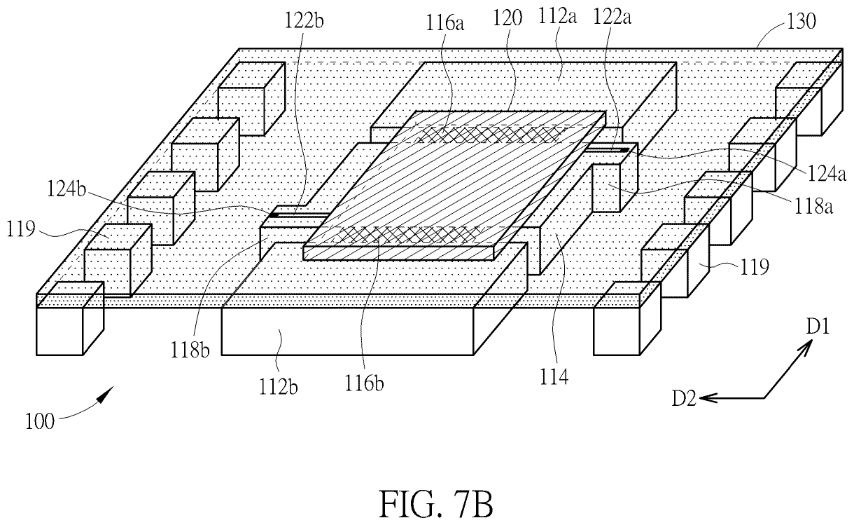

Referring now collectively to FIG. 7A and FIG. 7B, which respectively illustrate a schematic top view and an isometric view of a leadframe 100 and a die 120 within the structure as depicted in an alternative embodiment of the present disclosure. The difference between this embodiment and the previous one is that the die 120 is position above the sensing resistor portion 114 of the current sensing resistor. In this design, as illustrated in FIG. 7A and FIG. 7B, an isolation layer 130 is required between the die 120 and the leadframe to electrically isolate the two components. Additionally, it should also be noted that in this embodiment, the leads 112a/112b extend from opposite sides of the sensing resistor portion 114 of the leadframe, in contrast to the leads extending from same side in previous embodiment. Furthermore, in this embodiment, the leads 112a/112b are preferably offset from each other along the first direction D1. To electrically couple to the leads 112a/112b extending outward from the sensing resistor portion 114 along the second direction D2, conductive lines 122a/122b, such as copper traces, are formed on the isolation layer 130 to link the die 120 with the leadframe below. The conductive lines 122a/122b may also extend from opposite sides of the die 120 along the second direction D2. Additionally, vias (vertical interconnect accesses) 124a/124b are form in the isolation layer 130 to couple to the conductive lines 122a/122b with the leads 118a/118b beneath. This design further minimizes resistance variation in current measurement, as the leads 118a/118b are positioned away from each other on opposite sides of the current sensing resistor and offset along the second direction D2, thereby preventing interference of the sensing signal. The signal amplified by the die 120 may then be output to an external circuit, such as a PCB, through other conductive traces (not shown) on the isolation layer 130 and additional leads 119 of the leadframe 100. This amplified signal can subsequently be processed or analyzed by other components mounted on the PCB, such as the analog-to-digital converter 106 and the microcontroller 108, as depicted in FIG. 1.

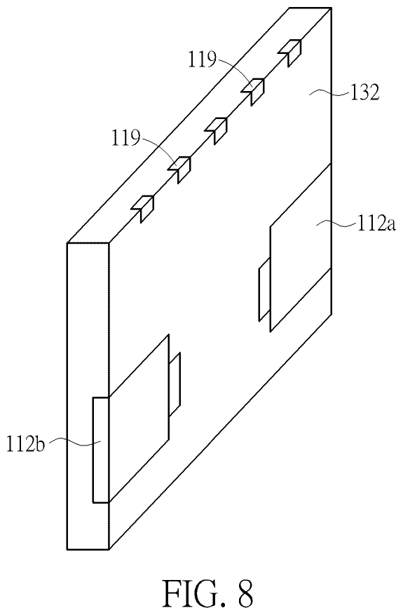

Refer now to FIG. 8, which shows an isometric view of the structure for current sensing according to one embodiment of the present disclosure. In the present disclosure, the components, including the leadframe 100 and die 120, are encapsulated within a molding compound 132 to form the structure. As depicted in FIG. 8, the portions such as the first terminal 112a, second terminal 112b and leads 119 remain exposed from the molding compound 132, allowing for electrical connections to external circuits, such as current source, load, or PCB.

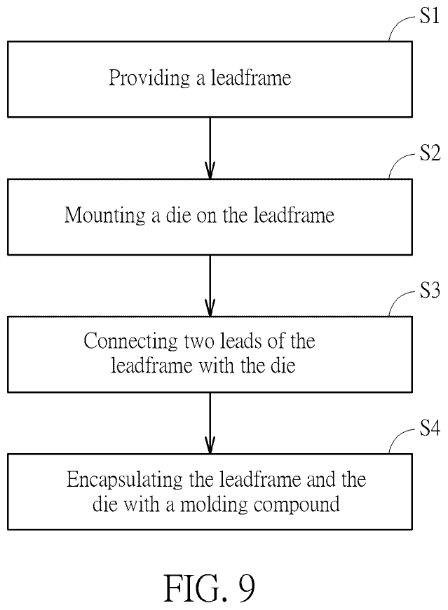

Refer now to FIG. 9, which illustrates a flowchart outlining the manufacturing process of the structure for current sensing, according to one embodiment of the present disclosure. Building on the previously described embodiment, the present disclosure also introduces a method for manufacturing the structure specifically designed for current sensing.

As shown in FIG. 9, in step S1, a leadframe (e.g., 100 in FIG. 6B) is first provided to serve as the foundational structure for the package components. The leadframe is typically fabricated through stamping or etching from metal materials such as copper or iron-nickel alloy. Its primary function is to provide mechanical support for the die and act as the electrical connection medium between the die and the PCB. Following the preparation of the leadframe, in step S2, a die (e.g., 120 in FIG. 6B) is then mounted onto the leadframe. The die is precisely mounted on the leadframe using an automated die bonding machine, ensuring accurate placement. Additionally, in step S3, a layer of thermal or conductive adhesive is usually applied to the designated mounting area of the leadframe to facilitate both thermal dissipation and electrical connection, particularly to electrically link the die to the leads (e.g., 118a/118b in FIG. 6B) extending from the sensing resistor portion of the leadframe. After the die is securely mounted and electrically coupled to the leadframe, in step S4, both the leadframe and the die are encapsulated within a molding compound (e.g., 132 in FIG. 8) to form the final structure of the present disclosure. The molding compound can protect the die from environmental influences and maintain the stability of the electrical connection. In the molding step, the leadframe and the die bonded thereon are placed into a mold, where they undergo injection molding using materials such as plastic or epoxy resin. The packaging material is injected into the mold under high temperature and high pressure, forming the molding compound that completely encapsulates the die and the conductive wires or traces, while leaving the terminals exposed for external connection. Following this, a die singulation process may be optionally performed to separate the entire package into multiple individual package units.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A structure for current sensing, comprising:
a leadframe, comprising:
a first terminal for measuring a current;
a second terminal positioned different from the first terminal;
a sensing resistor portion positioned between the first terminal and the second terminal;
a plurality of current rectifying portions respectively positioned between the first terminal and the sensing resistor portion, and between the second terminal and the sensing resistor portion, wherein the current rectifying portions couple the first terminal and the second terminal with the sensing resistor portion; and
a plurality of leads extending from the sensing resistor portion;
a die mounted on the leadframe, wherein the leads are coupled to the die; and
a molding component encapsulating the leadframe and the die.

2. The structure for current sensing of claim 1, wherein the leads extend from the sensing resistor portion along a second direction, and a width of the current rectifying portion in the second direction is smaller than a width of the first terminal in the second direction and smaller than a width of the second terminal in the second direction.

3. The structure for current sensing of claim 1, wherein the leads extend from the sensing resistor portion along a second direction, and a width of the current rectifying portion in the second direction is smaller than a width of the sensing resistor portion in the second direction.

4. The structure for current sensing of claim 1, wherein the second terminal is opposite to the first terminal along a first direction and the leads extend from the sensing resistor portion along a second direction, and a ratio of a length along the first direction to a width along the second direction of the current rectifying portion is over 0.02.

5. The structure for current sensing of claim 1, wherein the leads extend from the sensing resistor portion along a second direction, and a ratio of the width of the current rectifying portions to a width of the sensing resistor portion along the second direction is below 0.9.

6. The structure for current sensing of claim 1, wherein the second terminal is opposite to the first terminal along a first direction, and a cross-sectional area of the current rectifying portions in the first direction is smaller than a cross-sectional area of the sensing resistor portion in the first direction.

7. The structure for current sensing of claim 1, wherein the die comprises operational amplifier circuit.

8. The structure for current sensing of claim 7, wherein the leads are coupled respectively with the die.

9. The structure for current sensing of claim 1, wherein the leads extend from the sensing resistor portion along a second direction, and the leads extend from two opposite sides of the sensing resistor portion along the second direction.

10. The structure for current sensing of claim 9, wherein the second terminal is opposite to the first terminal along a first direction, and the leads are offset along the first direction.

11. The structure for current sensing of claim 1, further comprising an insulation layer between the die and the leadframe, wherein the leads are electrically coupled to the die by vias that extend through the insulation layer.

12. The structure for current sensing of claim 1, wherein the first terminal and the second terminal of the leadframe are symmetrical with respect to the sensing resistor portion.

13. The structure for current sensing of claim 1, wherein the second terminal is opposite to the first terminal along a first direction, and the current rectifying portions are aligned in the first direction.

14. A method of manufacturing a structure for current sensing, comprising:
providing a leadframe, wherein the leadframe comprises:
a first terminal for measuring a current;
a second terminal for measuring the current, wherein the second terminal is different from the first terminal;
a sensing resistor portion positioned between the first terminal and the second terminal;
a plurality of current rectifying portions respectively between the first terminal and the sensing resistor portion and between the second terminal and the sensing resistor portion, and the current rectifying portions couple to the first terminal and the second terminal with the sensing resistor portion; and
a plurality of leads extending from the sensing resistor portion;
mounting a die on the leadframe;
electrically coupling the leads to the die; and
encapsulating the leadframe and the die with a molding component.

15. The method of manufacturing a structure for current sensing of claim 14, further comprising forming an insulation layer on the leadframe, wherein the insulation layer is between the die and the leadframe.

16. The method of manufacturing a structure for current sensing of claim 15, further comprising forming vias in the insulation layer, and the leads are electrically coupled to the die by the vias that extend through the insulation layer.

17. The method of manufacturing a structure for current sensing of claim 14, wherein the leads extend from the sensing resistor portion along a second direction, and a width of the current rectifying portions in the second direction is smaller than a width of the first terminal in the second direction and smaller than a width of the second terminal along the second direction.

18. The method of manufacturing a structure for current sensing of claim 14, wherein the leads extend from the sensing resistor portion along a second direction, and a width of the current rectifying portions in the second direction is smaller than a width of the sensing resistor portion in the second direction.

19. The method of manufacturing a structure for current sensing of claim 14, wherein the die comprises operational amplifier circuit.

20. The method of manufacturing a structure for current sensing of claim 14, wherein the leads extend from the sensing resistor portion along a second direction, and the leads extend from two opposite sides of the sensing resistor portion along the second direction.
